(19) United States
(12) Patent Application Publication
(10) Pub. No.: US 2011/0013259 A1
(43) Pub. Date: Jan. 20, 2011

(54) MANUFACTURING METHOD FOR CHARGED PARTICLE MIGRATION TYPE DISPLAY PANEL, CHARGED PARTICLE MIGRATION TYPE DISPLAY PANEL, AND CHARGED PARTICLE MIGRATION TYPE DISPLAY APPARATUS

(75) Inventor: Kenichi Murakami, Kuwana-shi (JP)

Correspondence Address: BAKER BOTTS LLP;C/O INTELLECTUAL PROPERTY DEPARTMENT, THE WARNER, SUITE 1300, 1299 PENNSYLVANIA AVE, NW, WASHINGTON, DC, 20004-2400, US

(73) Assignee: BROTHER KOGYO KABUSHIKI KAISHA, Nagoya-shi (JP)

(21) Appl. No.: 12/892,302

(22) Filed: Sep. 28, 2010

Related U.S. Application Data
(63) Continuation-in-part of application No. PCT/JP2009/053206, filed on Feb. 23, 2009.

(30) Foreign Application Priority Data
Mar. 28, 2008 (JP) 2008-085839

(51) Int. Cl. G02F 1/167; B05D 5/06; C30B 33/08

(52) U.S. Cl. 359/296; 427/64; 216/23

(57) ABSTRACT

There is provided a manufacturing method for a charged particle migration type display panel which has a plurality of cells partitioned between two substrates placed opposite to each other by partition walls, and charged particles enclosed in the individual cells, the method including a partition wall forming step of forming the partition walls in one of the substrates, and an electrode film forming step of forming, by vapor deposition, an electrode film on a surface of the substrate where the partition walls are formed, wherein an electric contact is disconnected between the electrode film formed on the substrate surface and a surplus electrode film formed on a side face of the partition wall in the electrode film forming step by performing an insulating part forming step of forming an insulating part so shaped that a deposition material does not reach vicinities of at least bases of the partition walls before the electrode film forming step.

### TECHNICAL FIELD

The present invention relates to a manufacturing method for a charged particle migration type display panel which has charged particles enclosed in a plurality of cells partitioned between two substrates by partition walls, a charged particle migration type display panel, and a charged particle migration type display device, and, more particularly, to a manufacturing method for a charged particle migration type display panel, a charged particle migration type display panel, and a charged particle migration type display device, which disconnect an electric contact between an electrode film formed on a substrate surface and a surplus electrode film formed on a side face of a partition wall, thereby preventing coagulation of charged particles at the side face of the partition wall at the time of applying a voltage to the electrode film.

### BACKGROUND ART

Research and development have been made on display panels which effect display by moving charged particles (hereinafter called “charged particle migration type display panel”) as image display devices, such as portable terminals and electronic paper. The charged particle migration type display panel is configured to include a transparent substrate which has a common electrode formed thereon, and a back substrate which has a plurality of pixel electrodes formed thereon, and partition walls arranged between the transparent substrate and back substrate, and to have charged particles of a dark color like black and charged particles of light color like white enclosed in the plurality of cells partitioned by the partition walls. A predetermined voltage is applied to each pixel electrode to generate an electric field between the back substrate and the transparent substrate, so that the dark-colored or light-colored charged particles are migrated to the transparent substrate to display black, white, or gray.

Such a charged particle migration type display panel is generally manufactured by forming the pixel electrode and the partition walls on the back substrate, spraying the charged particles in the individual cells partitioned by the partition walls, and then tightly securing the transparent substrate which is placed opposite to the back substrate by an adhesive.

Conventional manufacturing methods for a charged particle migration type display panel include the following manufacturing method. According to the manufacturing method, first, a pixel electrode is formed on the substrate surface of the back substrate as a first step. As a second step, partition walls are formed on the substrate surface of the back substrate. As a third step, a liquid dispersion medium is filled into the individual cells partitioned by the partition walls using a dispersed type filling apparatus of an inkjet type. As a fourth step, the upper portions of the partition walls are sealed. As a fifth step, a front substrate which has a common electrode formed thereon beforehand is adhered to the back substrate in such a way that the common electrode faces the pixel electrode. According to the conventional manufacturing methods, the partition walls may also be formed by pressing a partition material with a stamper in the second step.

However, since the pixel electrode is formed on the rear-face side of the back substrate in the conventional manufacturing method for the charged particle migration type display panel, there is an extra distance caused by the thickness of the substrate, thereby raising the problem that the drive voltage should be set high.

One solution to the problem is to form the pixel electrode on the front-face side of the back substrate (face opposite to the transparent substrate) by vapor deposition. The step of forming partition walls by imprinting and the step of forming the pixel electrode will be described below as an example of a method of fabricating partition walls integrated with a back substrate by referring to FIGS. 11(a) to 11(d). FIG. 11(a) is an explanatory diagram exemplarily showing the step of forming the partition walls by imprinting, and FIGS. 11(b) to 11(d) are partly enlarged views of FIG. 11(a) which exemplarily shows the step of forming the pixel electrode.

In FIG. 11(a), a concavo-convex surface 101 corresponding to partition walls and individual cells is formed in a mold 100, and the concavo-convex surface 101 is heated and pressed against the substrate surface of the back substrate 20 to integrally form partition walls 30 and a plurality of cells 40 partitioned by the partition walls 30. Next, as shown in FIG. 11(b), the upper end portions of the partition walls 30 are covered with a resist 80. Then, as shown in FIG. 11(c), a pixel electrode 21 is formed on the inner substrate surface of the back substrate 20 by physical vapor deposition, such as vacuum deposition or sputtering. At this time, surplus electrode films 21a are formed on the side faces of the partition walls 30 (in FIG. 11(c), the surface of the resist 10 is actually covered with a deposition material too, which is omitted for the sake of the descriptive convenience). Finally, as shown in FIG. 11(d), the resist 80 covering the upper end portions of the partition walls 30 is removed. This disconnects an electric contact between a common electrode (not shown) on the transparent substrate which is mounted on the upper end faces of the partition walls 30 and the surplus electrode films 21a formed on the side faces of the partition walls 30.

According to the manufacturing method mentioned above, however, the surplus electrode films 21a formed on the side of the partition walls 30 will be electrically connected to the pixel electrode 21 on the back substrate 20. When a predetermined voltage is applied to the pixel electrode 21, therefore, the charged particles required for display are coagulated at the surplus electrode films 21a, which reduces both the response speed of the charged particles, and the display contrast, thereby adversely affecting the display quality. The foregoing manufacturing method cannot therefore keep good display quality stable over a long period of time.

### DISCLOSURE OF THE INVENTION

In view of the above problems, it is an object of the invention to provide a manufacturing method for a charged particle migration type display panel, a charged particle migration type display panel, and a charged particle migration type display device, which disconnect an electric contact between an electrode film formed on a substrate surface and a surplus electrode film formed on a side face of a partition wall to prevent coagulation of charged particles at the side face of the partition wall, thereby making it possible to improve both the response speed of charged particles, and the display contrast and ensure stable display quality over a long period of time.

To achieve the above object, according to one embodiment of the invention, there is provided a manufacturing method for a charged particle migration type display panel which has a plurality of cells partitioned between two substrates placed opposite to each other by partition walls and charged particles enclosed in the individual cells, the method including a partition wall forming step of forming the partition walls in one of the substrates, and an electrode film forming step of forming, by vapor deposition, an electrode film on a surface of the substrate where the partition walls are formed, wherein an electric contact is disconnected between the electrode film formed on the substrate surface and a surplus electrode film formed on a side face of the partition wall in the electrode film forming step by performing an insulating part forming step of forming an insulating part so shaped that a deposition material does not reach vicinities of at least bases of the partition walls before the electrode film forming step.

### BRIEF DESCRIPTION OF THE DRAWINGS

FIG. 1 is a side cross-sectional view exemplarily showing a charged particle migration type display panel according to one embodiment of the invention.

FIG. 2 is a partial cross-sectional plan view exemplarily showing the charged particle migration type display panel.

FIG. 3 is a flowchart illustrating the general flow of a manufacturing method for a charged particle migration type display panel according to the embodiment.

FIG. 4 is a flowchart illustrating the flow of an insulating part forming step in the manufacturing method.

FIGS. 5(a) to 5(d) are explanatory diagrams exemplarily showing the flow of the insulating part forming step.

FIGS. 6(a) to 6(d) are explanatory diagrams exemplarily showing a partition-wall upper end portion resist step, an electrode film forming step, and a partition-wall upper end portion resist removal step which follow the insulating part forming step.

FIGS. 7(a) to 7(c) are explanatory diagrams exemplarily showing another mode of an insulating part, which has a concavo-convex shape formed in the vicinity of the base of the partition wall.

FIG. 8 is an explanatory diagram exemplarily showing a further mode of an insulating part formed by shaping the side face of the partition wall into a reverse tapered shape or a reverse wedge shape.

FIGS. 9(a) to 9(c) is an explanatory diagrams exemplarily showing how to shape the side face of the partition wall into a reverse tapered shape or a reverse wedge shape.

FIG. 10(a) is an explanatory diagram showing an embodiment in which partition walls formed integral with a transparent substrate is provided with an insulating part, and FIG. 10(b) is an explanatory diagram showing an embodiment of a charged particle migration type display panel of a passive matrix type is provided with an insulating part.

FIG. 11(a) is an explanatory diagram exemplarily showing the step of forming partition walls by imprinting, and FIGS. 11(b) to 11(d) are partly enlarged views of FIG. 11(a), exemplarily showing the step of forming a pixel electrode.

### DETAILED DESCRIPTION OF THE INVENTION

### General Description

According to one embodiment of the invention, there is provided a manufacturing method for a charged particle migration type display panel which has a plurality of cells partitioned between two substrates placed opposite to each other by partition walls, and charged particles enclosed in the individual cells, the method including a partition wall forming step of forming the partition walls in one of the substrates, and an electrode film forming step of forming, by vapor deposition, an electrode film on a surface of the substrate where the partition walls are formed, wherein an electric contact is disconnected between the electrode film formed on the substrate surface and a surplus electrode film formed on a side face of the partition wall in the electrode film forming step by performing an insulating part forming step of forming an insulating part so shaped that a deposition material does not reach vicinities of at least bases of the partition walls before the electrode film forming step.

According to this method, since an insulating part so shaped that a deposition material does not reach the vicinities the bases of the partition walls is formed in the insulating part forming step, it is possible to disconnect an electric contact between the electrode film formed on the substrate surface and the surplus electrode film formed on the side face of the partition wall in the subsequent electrode film forming step. This makes it possible to prevent coagulation of charged particles at the side face of the partition wall at the time of applying a voltage to the electrode film. As a result, both the response speed of charged particles, and the display contrast are improved to ensure stable display quality over a long period of time.

Preferably, in the manufacturing method for a charged particle migration type display panel of the invention mentioned above, a recessed groove extending along the base of the partition walls as the insulating part is formed as the insulating part.

According to this method, in the electrode film forming step, a deposition material is difficult to reach inside the recessed groove formed in the vicinity of the base of the partition wall, thereby making it possible to disconnect an electric contact between the electrode film formed on the substrate surface and the surplus electrode film formed on the side face of the partition wall.

Preferably, in the manufacturing method for a charged particle migration type display panel according to the invention, the shape of the vicinity of the base of the partition wall has a reverse tapered shape or a reverse wedge shape to be tapered toward the substrate surface.

According to this method, the reverse tapered shape or reverse wedge shape of the vicinities of the bases of the partition walls makes it difficult for a deposition material to reach the vicinity of the deep base of the partition wall, thereby making it possible to disconnect an electric contact between the electrode film formed on the substrate surface and the surplus electrode film formed on the side face of the partition wall.

Preferably, in the manufacturing method for a charged particle migration type display panel according to the invention, a projection extending along the partition wall is formed above the base of the partition wall, so that the vicinity of the base becomes the insulating part so shaped that the deposition material does not reach thereto.

According to this method, in the electrode film forming step, the formation of the projection above the base of the partition wall makes it difficult for a deposition material to reach the vicinity of the deep base of the partition wall, thereby making it possible to disconnect an electric contact between the electrode film formed on the substrate surface and the surplus electrode film formed on the side face of the partition wall.

Preferably, in the insulating part forming step, the insulating part is formed by etching either at least one of the partition wall and the substrate surface. According to this method, an insulating part of a specified shape can be easily formed at a minute partition wall.

Preferably, in the partition wall forming step, the partition walls are formed integral on a flexible substrate as the substrate by a mold. This method can prevent the partition walls from being separated by bending of the flexible substrate.

It is preferable that the manufacturing method for a charged particle migration type display panel according to the invention preferably should further comprise a step of masking an upper end portion of the partition wall with a resist before the electrode film forming step, and a step of removing the resist after the electrode film forming step, and an electric contact between the surplus electrode films respectively formed at the vicinities of the upper end portions on both side faces of the partition wall and an electrode film on the other substrate which is mounted on the upper end portions should be disconnected.

According to this method, the formation of the surplus electrode film can be prevented from being formed at an upper end portion of the partition wall in the electrode film forming step, thereby making it possible to disconnect an electric contact between the surplus electrode film formed on the side face of the partition walls and the electrode film on the other substrate which is mounted on the upper end portion of the partition wall. As mentioned above, an electric contact between the surplus electrode film formed on the side face of the partition wall and the electrode film on one substrate where the partition walls are formed can be disconnected by the insulating part formed in the vicinity of the base of the partition wall. As a result, it is possible to disconnect an electric contact between two substrates which are placed opposite each other via the partition walls.

When the upper end portions of the partition walls where a plurality of cells arranged in a matrix form are to be formed are masked with a separate member, such as a mask film, it is difficult to position partition walls with minute and complicated shapes with the mask film or the like. When one substrate where the partition walls are formed is a resin substrate like a flexible substrate, particularly, it is more difficult to implement positioning with the mask film or the like due to the influence of contraction or the like of the substrate. The masking of the upper end portions of the partition walls with a resist as done in the manufacturing method according to the invention can permit the difficult step of positioning the partition walls with the mask film or the like to be skipped, thus making it possible to reduce the manufacturing cost.

To achieve the foregoing object, a charged particle migration type display panel according to the invention is characterized by being manufacturing by each of the above-described methods of the invention. In addition, a charged particle migration type display device according to the invention is characterized by having the charged particle migration type display panel according to the invention. According to the charged particle migration type display panel and the charged particle migration type display device, as an insulating part so shaped that a deposition material does not reach the vicinities the bases of the partition walls is formed in the insulating part forming step, it is possible to disconnect an electric contact between the electrode film formed on the substrate surface and the surplus electrode film formed on the side face of the partition wall in the subsequent electrode film forming step. This makes it possible to prevent coagulation of charged particles at the side face of the partition wall at the time of applying a voltage to the electrode film. As a result, both the response speed of charged particles, and the display contrast are improved to ensure stable display quality over a long period of time.

### EFFECT OF THE INVENTION

The manufacturing method for a charged particle migration type display panel, the charged particle migration type display panel, and the charged particle migration type display device according to the invention disconnect an electric contact between an electrode film formed on the substrate surface and the surplus electrode film formed on the side face of the partition wall to prevent coagulation of charged particles at the side face of the partition wall, thereby making it possible to improve both the response speed of charged particles, and the display contrast, and ensure stable display quality over a long period of time.

### DESCRIPTION OF ILLUSTRATED EMBODIMENT

A manufacturing method of a charged particle migration type display panel and a charged particle migration type display panel according to an embodiment of the invention will be described below referring to the accompanying drawings.

### <Outline of Charged Particle Migration Type Display Panel>

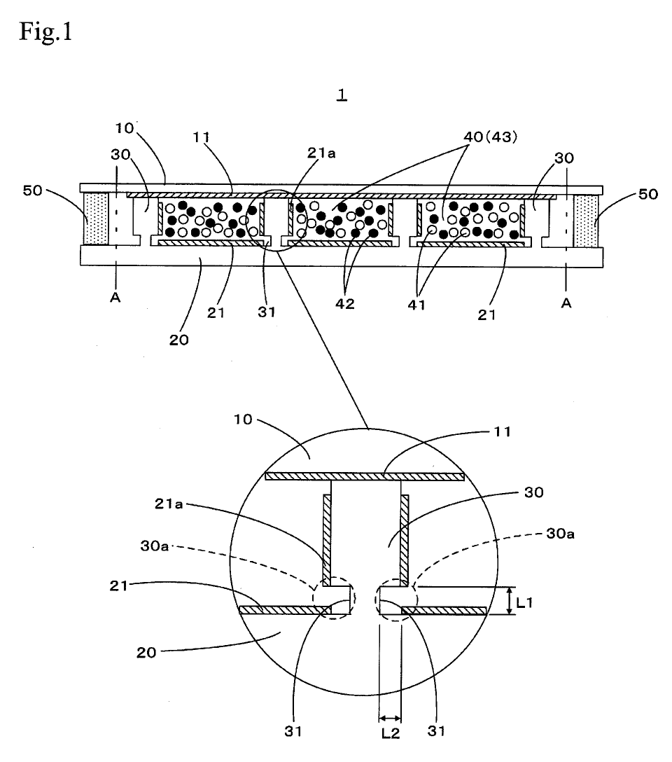

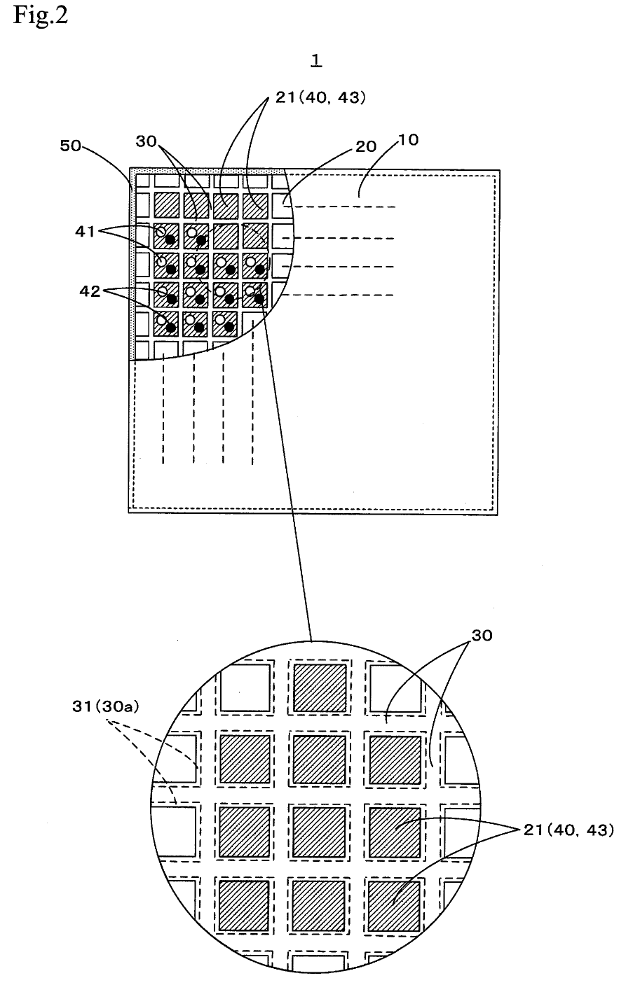

First, the outline of the charged particle migration type display panel according to the embodiment will be described referring to FIGS. 1 and 2.

A and A in FIG. 1 are omission lines. For the sake of descriptive convenience, FIG. 1 provides a schematic illustration showing the structure of part of a charged particle migration type display panel 1 inside the omission lines A, A, and showing both end sides of the charged particle migration type display panel 1 outside the omission lines A, A. Actually, as shown in FIG. 2, the region between a transparent substrate 10 and a back substrate 20 is partitioned into a plurality of cells 40, 40, 40, . . . by the partition walls 30. One cell 40 corresponds to one pixel, and the structure shown inside the omission lines A, A in FIG. 1 is the general structure which has multiple cells continuously laid out in a matrix form. Of course, it may take a structure which has a plurality of cells 40 provided in one pixel, or may take a structure which has one cell 40 correspond to a plurality of pixels.

In FIG. 1, the charged particle migration type display panel 1 includes the transparent substrate 10 provided on the display side (upper side in the diagram), and the back substrate 20 disposed apart from the transparent substrate 10 by a given interval and substantially in parallel thereto. According to the embodiment, the transparent substrate 10 and the back substrate 20 are both flexible substrates made of polyethylene terephthalate. A common electrode (electrode film) 11 formed of a transparent member is formed at the back surface of the transparent substrate 10. A plurality of pixel electrodes (electrode films) 21 provided for the respective pixels are formed on the top surface of the back substrate 20.

As mentioned above, the partition walls 30 are disposed in a vertical/horizontal lattice pattern between the transparent substrate 10 and the back substrate 20. White charged particles (light-colored charged particle) 41 and black charged particles (dark color charged particle) 42 are filled in the individual cells 40, 40, 40, . . . partitioned by the transparent substrate 10, the back substrate 20, and the partition walls 30. Further, each cell 40 is tightly sealed by fixing the peripheral edges of the transparent substrate 10 and the back substrate 20 with an adhesive 50, such as an ultraviolet curing resin.

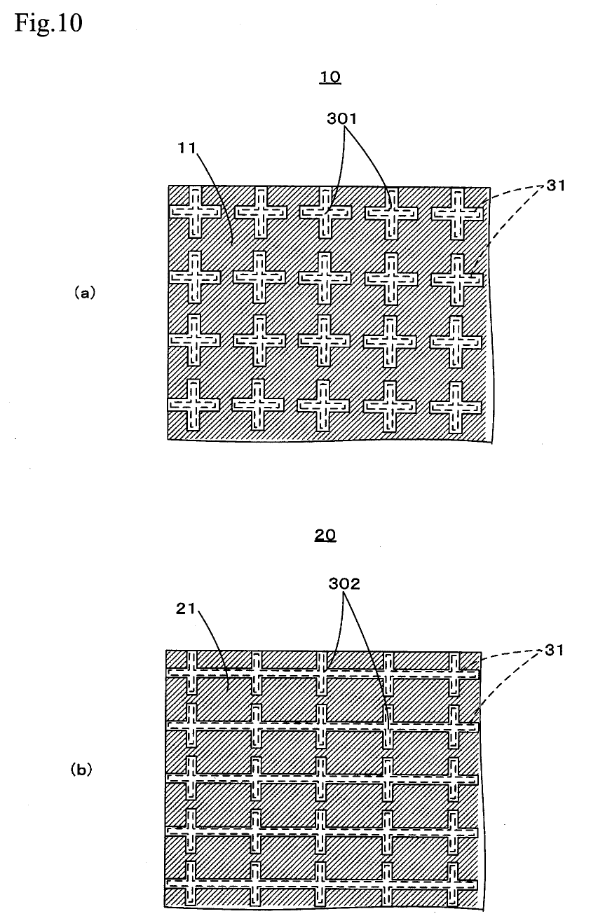

The shapes of the partition walls 30 are not limited to the continuous vertical/horizontal lattice pattern shown in FIG. 2; for example, the shapes may be cross shapes with the partition walls in the vertical and horizontal directions being disposed completely discontinuous (see FIG. 10(a)), or may form a lattice pattern with either the vertical partition walls or the horizontal partition walls being discontinuous (see FIG. 10(b)).

Although the transparent substrate 10 is a flexible substrate made of polyethylene terephthalate in the embodiment, it is not limited thereto, but can be formed of various materials which have high transparency and insulation. For example, polyethylenenaphthalate, polyether sulphone, polyimide, glass, etc. can be used as a material for the transparent substrate 10.

The common electrode 11 has high transparency is formed of a material which can be used as an electrode. For example, indium oxide tin (ITO) which has tin doped into indium oxide which is a metallic oxide, tin oxide doped with fluoride, zinc oxide doped with indium, etc. can be used as a material for the common electrode 11.

Likewise, although the back substrate 20 is a flexible substrate made of polyethylene terephthalate in the embodiment, the back substrate 20 can be formed of various materials which have high insulation. For example, inorganic materials, such as glass and a metallic film which is subjected to an insulation treatment, and organic materials other than polyethylene terephthalate can be used as a material of the back substrate 20. Unlike the transparent substrate 10, the back substrate 20 may be transparent or may be opaque.

The pixel electrode 21 is formed of a metallic material with high electrical conductivity, such as gold or copper. According to the embodiment, after the partition walls 30 are integrally formed on the substrate surface of the back substrate 20, the metallic material (deposition material) is vapor deposited on the substrate surface for form the pixel electrode 21. Physical vapor deposition (PVD), such as vapor deposition or sputtering, is preferable as the method of forming the pixel electrode 21. It is to be noted that as long as an electrode film of a metallic material can be formed on the substrate surface of the back substrate 20, another physical vapor deposition using chemical method or chemical vapor deposition (CVD) may be used. This is because as an electrode film (which is not restricted to the pixel electrode 21) is formed by vapor deposition after formation of the partition walls 30, it is possible to obtain the insulating effect which is originated from the formation of the insulating part 31 to be described below in the vicinity of the base of the partition wall 30 is acquired.

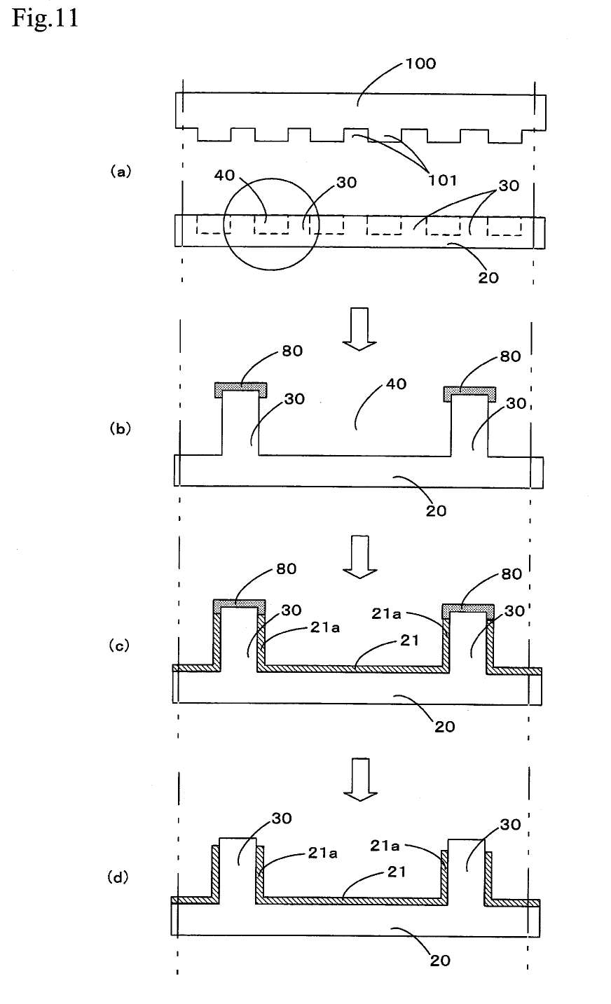

According to the embodiment, the partition walls 30 are integrally formed on the back substrate 20 made of polyethylene terephthalate by the imprinting (see FIG. 11(a)). As shown in the partly enlarged view in FIG. 1, the insulating part 31 having the shape of a recessed groove extending along the vicinity of a base 30a of the partition wall 30 is formed. As shown in the partly enlarged view in FIG. 2, the insulating part 31 with the recessed groove shape surrounds the pixel electrode 21 of a quadrangular shape in each cell 40. The formation of such insulating part 31 disconnects an electric contact between the pixel electrode 21 on the substrate surface of the back substrate 20 and the surplus electrode film 21a on the side face of the partition walls 30.

That is, in a preceding stage to the vapor deposition of the pixel electrode 21 onto the substrate surface of the back substrate 20, the deep insulating part 31 of the recessed groove shape which prevents a deposition material from reaching the vicinity of the base 30a of the partition wall 30 is formed beforehand, after which an electric contact between the pixel electrode 21 formed on the substrate surface of the back substrate 20 and the surplus electrode film 21a formed on the side face of the partition walls 30 is disconnected.

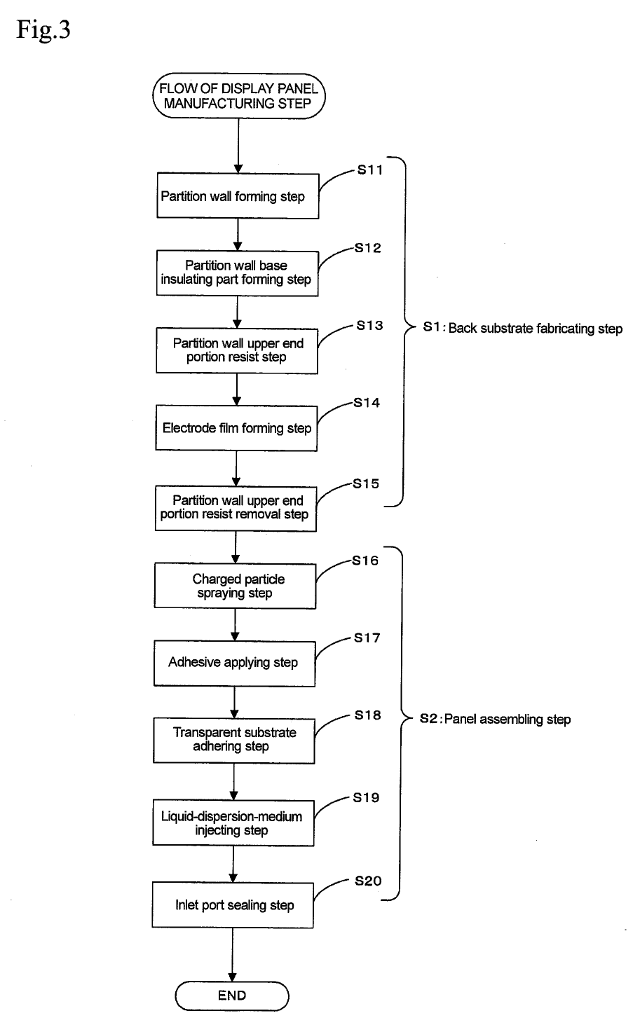

It is preferable that the height, L1, and the width, L2, of the insulating part 31 shown in FIG. 1 should both be twice or more of the thickness of the pixel electrode 21. Actually, with the pixel electrode 21 having a thickness of about 150 nm or so, and the height L1 and the width L2 being 300 nm or so, it is probable that the deposition material would not reach the deep portion of the insulating part 31. To decrease a size variation in the manufacturing process, it is preferable to set the height L1 and width L2 to 1 μm or greater. The manufacturing method for the charged particle migration type display panel 1 which includes the step of forming such insulating part 31 will be described in detail later referring to FIGS. 3 to 6.

Each of the cells 40 partitioned by the partition walls 30 may have a dry structure having charge particles 41 and 42 alone sealed therein, or a wet structure having the liquid dispersion medium 43 sealed therein. A mixed solution containing a solution having high insulation, such as hydrocarbon or silicone oil, and a disperser, such as a surface-active agent or alcohol, can be used as the liquid dispersion medium 43. Further, with the liquid dispersion medium 43 colored black or white, it is also possible to adopt the structure where charged particles 41, 42 are set to have a monotonous color of white or black.

The charged particles 41, 42 in use can be of a chargeable material, e.g., a paint or a dye formed of an organic compound or an inorganic compound, or a paint or a dye covered with a synthetic resin. In addition, the white charged particles 41 and the black charged particles 42 are charged to different polarities, namely, positive and negative polarities. The charged particles 41, 42 are not limited to white and black, and light-colored charged particles other than white and dark color charged particles other than black can be used as well. For the sake of descriptive convenience, the diameter of the charged particles 41, 42 is shown larger in the diagram as compared with the size of the partition walls 30.

### <Display Principle of Charged Particle Migration Type Display Panel>

Next, the display principle of the above-described charged particle migration type display panel 1 will be described briefly. It is supposed that the white charged particles 41 is charged negative, and the black charged particles 42 is charged positive in FIG. 1. With the potential of the transparent substrate 10 being taken as a reference potential, when a predetermined voltage is applied to the pixel electrode 21 to set the back substrate 20 negative, the white charged particles 41 are distributed near the transparent substrate 10, and the black charged particles 42 are distributed near the back substrate 20. As a result, white is displayed on the transparent substrate 10.

With the transparent substrate 10 being taken as a reference potential, when a predetermined voltage is applied to the pixel electrode 21 to set the back substrate 20 positive, the white charged particles 41 are distributed near the back substrate 20, and the black charged particles 42 are distributed near the transparent substrate 10. As a result, black is displayed on the transparent substrate 10.

Based on the above principle, the individual charged particles 41, 42 can be migrated by applying a predetermined voltage to the pixel electrode 21 to control the electric field between the transparent substrate 10 and the back substrate 20, so that the display can be rewritten for each pixel.

### <Manufacturing Method for Charged Particle Migration Type Display Panel>

The manufacturing method for the charged particle migration type display panel according to the embodiment of the invention will be described referring to FIGS. 3 to 6.

The following description mainly covers the step of fabricating the back substrate 30, and detailed descriptions on the step of forming the common electrode 11 on the transparent substrate 10, which is performed separately from the fabrication step, and the same steps as those of the related art will be omitted. The charged particle migration type display panel 1 manufactured by the present method adopts a wet structure which has the charged particles 41, 42 and the liquid dispersion medium 43 enclosed in each cell 40.

In FIG. 3, the present manufacturing method is mainly separated into a back substrate fabricating step S1 of mainly forming the partition walls 30, the insulating parts 31, and the lower electrodes 21 on the back substrate 20, and a panel assembling step S2 of spraying the charged particles 41, 42 to the back substrate 20 which has undergone the former step, and carrying out secure adhesion or the like of the transparent substrate 10 to assemble the charged particle migration type display panel 1.

### <<Back Substrate Fabricating Step S1>>

### <<<Partition Wall Forming Step S11>>>

In the back substrate fabricating step S1 in FIG. 3, a partition wall forming step S11 is carried out first. In this partition wall forming step S11, the partition walls 30 are integrally formed on the substrate surface of the back substrate 20 by imprinting. That is, as shown in FIG. 11(a), the concavo-convex surface 101 of the mold 100 is heated and pressed against the inner surface of the substrate surface of the back substrate 20 to integrally form the partition walls 30 on the substrate surface and form a plurality of cells 40 partitioned by the partition walls 30.

### <<<Insulating Part Forming Step S12>>>

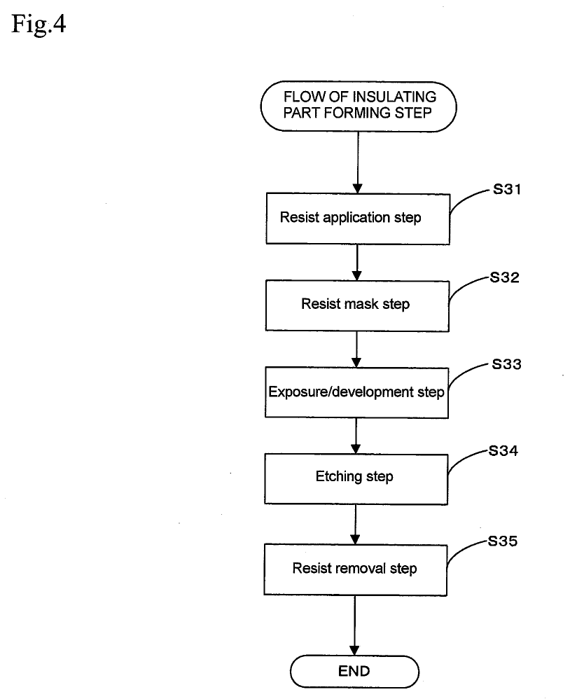

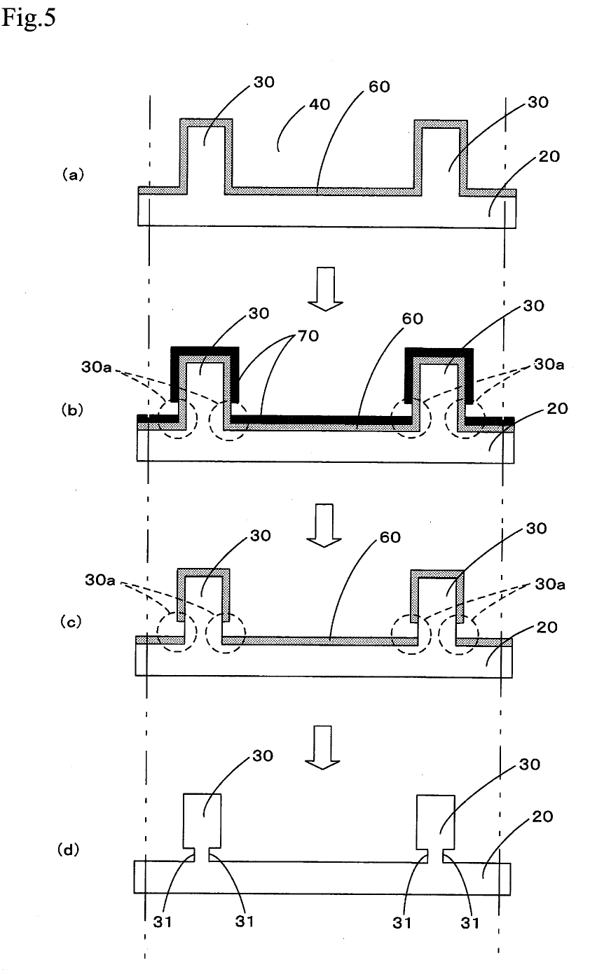

Subsequently, an insulating part forming step S12 of forming the insulating parts 31 in the vicinities of the bases of the partition walls 30 is carried out. One example of the insulating part forming step S12 will be elaborated, referring to FIG. 4 and FIGS. 5(a) to 5(d). FIG. 4 and FIGS. 5(a) to 5(d) merely show one example of the method of forming the insulating parts 31 at the partition walls 30, and the insulating parts 31 can be formed by other methods.

In the insulating part forming step S12, a resist application step S31 shown in FIG. 4 is carried out first. In the resist application step S31, as shown in FIG. 5(a), a resist 60 is applied to the entire substrate surface of the back substrate 20 including the partition walls 30. In an etching step S34 to be described later, the resist 60 is applied to prevent the chemical dissolution of parts other than insulating parts 31.

The entire substrate surface of the back substrate 20 including the partition walls 30 may be covered with an SiO₂ thin film in place of the resist 60. In this case, the SiO₂ thin film is formed on the surfaces of the back substrate 20 and the partition walls 30 by sputtering or vacuum vapor deposition.

Subsequently, a resist mask step S32 is carried out. In the resist mask step S32, as shown in FIG. 5(b), except for portions corresponding to the base vicinities 30a of the partition walls 30, the resist 60 applied to the entire substrate surface of the back substrate 20 is covered with the mask 70. This mask 70 is also a resist or film resist, and is arranged through the following two steps. As the first step, a resist to be the mask 70 is arranged only on the substrate surface of the back substrate 20 by contact printing or transfer. As the second step, tension is applied to a film resist to be the remaining masks 70, only the upper portions of the partition walls 30 are laminated by the film resist in the state, and heat flow is performed on the film resist. As a result, the mask 70 as shown in FIG. 5(b) is formed. It is to be noted that a final pattern can be obtained by another scheme without forming the mask 70 arranged at the upper portion of the substrate surface.

Next, an exposure/development step S33 is carried out. This exposure/development step S33 removes only the resist 60 in the base vicinities 30a of the partition walls 30 which are not covered with the mask 70, leaving the resist 60 covering the other back substrate 20 and the partition walls 30, as shown in FIG. 5(c).

Next, the etching step S34 is carried out. In the etching step S34, the entire substrate surface of the back substrate 20 shown in FIG. 5(c) is dipped in an etching reagent. Then, only the base vicinities 30a of the partition walls 30 which are not covered with the resist 60 are dissolved in the etching reagent, thereby forming the insulating parts 31 with the shape of a recessed groove at the base vicinities 30a of the partition walls 30 (see FIG. 5(d)).

Thereafter, a resist removal step S35 is carried out and the resist 60 covering the back substrate 20 and the partition walls 30 is removed. This completes the back substrate 20 which has the partition walls 30 having the insulating parts 31 formed in the vicinities of the bases, as shown in FIG. 5(d). The insulating part forming step S12 in FIG. 3 is completed in this way.

### <<<Partition Wall Upper End Portion Resist Step S13 to Resist Removal Step S15>>>

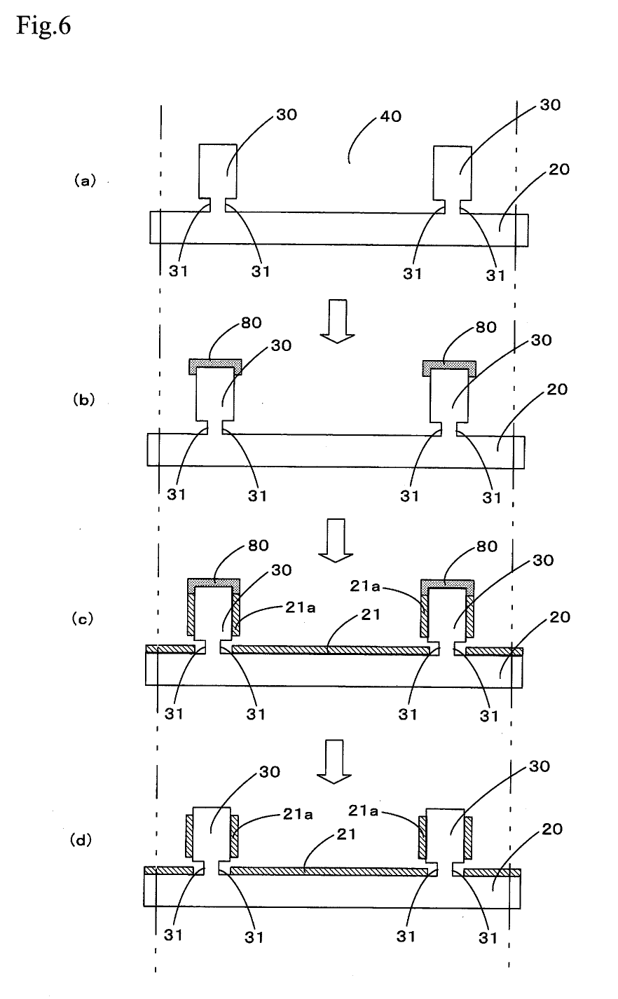

Next, a partition wall upper end portion resist step S13, an electrode film forming step S14, and a partition wall upper end portion resist removal step S15 will be described in detail, referring to FIG. 3 and FIGS. 6(a) to 6(d).

First, the partition wall upper end portion resist step S13 is carried out. A resist 80 covers the upper end portions of the partition walls 30 of the back substrate 20 (see FIG. 6(a)) which has undergone the aforementioned insulating part forming step S12 in the partition wall upper end portion resist step S13 (see FIG. 6(b)). This resist 80 is also placed by laminating only the upper end portions of the partition walls 30 with a tension-applied film resist, and then performing heat flow on the film resist. The resist 80 prevents the surplus electrode film from being formed at the upper end portions of the partition walls 30 in the electrode film forming step S14 to be described below.

Subsequently, the electrode film forming step S14 is carried out. In the electrode film forming step S14, a metallic material is deposited on the substrate surface of the back substrate 20 using physical vapor deposition, such as sputtering, thereby forming an electrode film. Then, as shown in FIG. 6(c), an electrode film is formed on the substrate surface of the back substrate 20 and the side faces of the partition walls 30, except for the deep portion of the insulating parts 31 with the recessed groove shape and the upper end portions of the partition walls 30 covered with the resist 80. As a result, the pixel electrode 21 needed is formed at the substrate surface of the back substrate 20, while the unnecessary surplus electrode 21a is formed at the side faces of the partition walls 30. An electric contact between the pixel electrode 21 and the surplus electrode film 21a is disconnected by the insulating part 31 formed in the vicinity of the base of the partition wall 30.

Thereafter, the partition wall upper end portion resist removal step S15 is carried out. As shown in FIG. 6(d), the resist 80 covering the upper end portions of the partition walls 30 is removed. As mentioned above, as a result of preventing the surplus electrode parts from being formed at the upper end portions of the partition walls 30 by the resist 80, it is possible to disconnect an electric contact between the surplus electrode films 21a formed on the side faces of the partition walls 30 and the common electrode 11 of the transparent substrate 10 mounted on the upper end portions of the partition walls 30. Since the electric contact between the surplus electrode films 21a of the partition walls 30 and the pixel electrodes 21 of the back substrate 20 is disconnected by the insulating parts 31, the electric contact between the common electrode 11 of the transparent substrate 10 and the pixel electrodes 21 of the back substrate 20 can also be disconnected. Through the above process, the back substrate fabricating step S1 is completed.

### <<<Panel Assembling Step S2>>>

Subsequently, the panel assembling step S2 in FIG. 3 is carried out. In the panel assembling step S2, a charged particle spraying step S16 is carried out first. In the particle spraying step S16, the white charged particles 41 and the black charged particles 42 are sprayed onto the back substrate 20 shown in FIG. 6(d) using the nozzle which is not illustrated. The charged particles 41, 42 needed for monotonous color display are retained inside the individual cells 40, 40, 40, . . . partitioned by the partition walls 30 (see FIGS. 1 and 2).

Next, an adhesive applying step S17 is carried out. In the adhesive applying step S17, an adhesives 50 (see FIGS. 1 and 2), such as ultraviolet curing resin, is applied along the peripheral edge of the back substrate 20 which has undergone the charged particle spraying step S16.

Next, a transparent substrate adhering step S18 is carried out. In the transparent substrate adhering step S18, the transparent substrate 10 (see FIGS. 1 and 2) is placed opposite to the back substrate 20 whose peripheral edge is applied with the adhesives 50, and the peripheral edges of the back substrate 20 and the transparent substrate 10 are tightly secured by the adhesives 50. As mentioned in the description of the back substrate fabricating step S1, the prevention of the formation of the surplus polar zone at the upper end portions of the partition walls 30 by the resist 80 (see FIG. 6(d)) results in achieving the condition that the surplus electrode films 21a formed on the side faces of the partition walls 30 and the common electrode 11 on the transparent substrate 10 mounted on the upper end portions of the partition walls 30 do not contact electrically in the transparent substrate adhering step S18.

Next, a liquid-dispersion-medium injecting step S19 is carried out. In the liquid-dispersion-medium injecting step S19, a liquid dispersion medium 43 is injected between the transparent substrate 10 and the back substrate 20 from an unillustrated inlet port which is formed in the transparent substrate 10 or the back substrate 20. The liquid dispersion medium 43 injected from the inlet port fills inside each cell 40. Then, the inlet port is sealed with a sealing compound in an inlet port sealing step S20. In this way, the panel assembling step S2 is completed, completing the charged particle migration type display panel 1 shown in FIGS. 1 and 2.

### Other Embodiments of Insulating Part

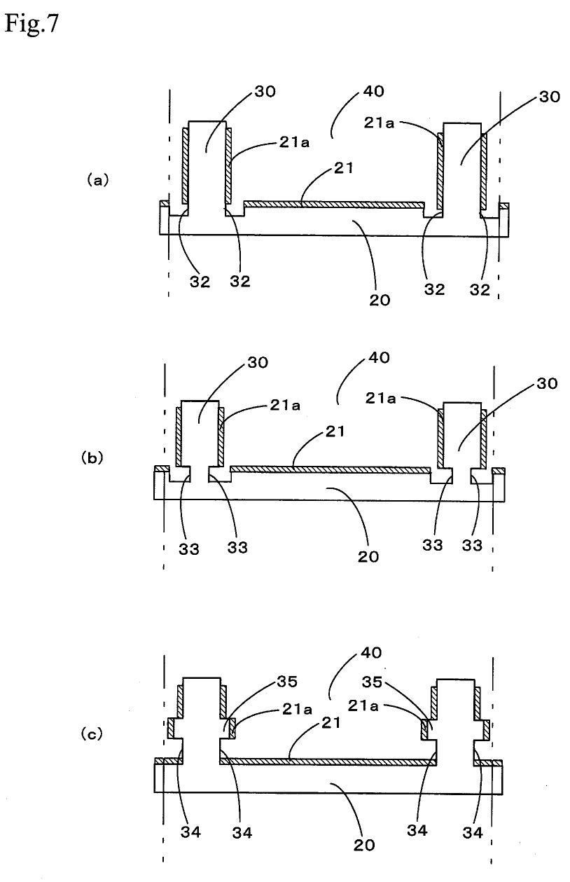

The insulating part formed in the vicinity of the base of the partition wall 30 is not limited to the form of the insulating part 31 exemplified in the foregoing description of the embodiment. For example, the insulating part may take the forms of insulating parts 32 to 34 shown in FIGS. 7(a) to 7(c).

The insulating part 32 shown in FIG. 7(a) has a recessed groove shape obtained by dissolving only the substrate surface of the back substrate 21 in the vicinity of the base of the partition wall 30 by etching. In case of such an insulating part 32, an electric contact between the pixel electrode 21 and the surplus electrode 21a can be disconnected without decreasing the width in the vicinity of the base of the partition wall 30.

For example, such insulating parts 32 can be simultaneously formed by embossing at the time of integrally forming the partition walls 30 by imprinting. Namely, heat imprinting of the substrate surface of the back substrate 20 should be carried out using a mold with an inverted pattern of the shapes of the partition walls 30 and the insulating parts 32 shown in FIG. 7(a). The dimensions of the depth and breadth of the insulating parts 32 are preferably about twice the thickness of the pixel electrode 21, and if the depth and the breadth are both 1 μm or greater, the deposition material will not reach into the recessed groove. It is also possible to form the insulating parts 32 by etching.

The insulating part 33 shown in FIG. 7(b) is the combination of the insulating part 31 and the insulating part 32 mentioned above, and has a recessed groove shape obtained by dissolving both the vicinity of the base of the partition wall 30 and the substrate surface of the back substrate 21 in that location by etching. In case of such an insulating part 33, the deposition material is difficult to reach a deeper portion of the insulating part 33, thereby making it possible to more surely disconnect an electric contact between the pixel electrode 21 and the surplus electrode 21a.

For example, such an insulating part 33 can be formed in the following two steps. As the first step, heat imprinting of the substrate surface of the back substrate 20 is performed using a mold similar to the one shown in FIG. 7(a). As a result, recessed grooves equivalent to the insulating parts 32 in FIG. 7(a) are formed. In consideration of the subsequent etching, however, the recessed grooves are formed shallower (for example, less than 1 μm) than the insulating parts 32. As the second step, an epoxy-based resin of about 1 μm in thickness is formed on the substrate surface of the back substrate 20 by contact printing. Then, an etching reagent (KOH or the like) is dropped so that the height from the epoxy-based resin film to the liquid level becomes 1 μm or so. Accordingly, the etching reagent is filled in the recessed grooves formed in the first step, and those portions of the recessed grooves which are exposed to the etching reagent are dissolved. Then, when the dissolution of the recessed grooves progresses to 1 μmin the depth direction and the horizontal direction, rinse with pure water is executed. As a result, the insulating parts 33 with the shape shown in FIG. 7(b) are formed. Finally, the mask for the epoxy-based resin film is removed by plasma ashing. After forming the recessed grooves in the first step, an etching reagent may be dropped into the recessed grooves to form the insulating parts 33, without forming the mask for the epoxy-based resin film.

The insulating part 34 shown in FIG. 7(c) is patterned in such a way that eaves-like projections 35 extending along the partition walls 30 are formed above the bases of the partition walls to prevent the deposition material from reaching the vicinities of the bases of the partition walls 30. Such an insulating part 34 can also disconnect an electric contact between the pixel electrode 21 and the surplus electrode 21a.

Such an insulating part 34 can be formed, for example, in the following two steps. As the first step, heat imprinting of the substrate surface of the back substrate 20 is performed to form the partition walls 30 with a protruding cross-sectional shape. In the second step, an etching reagent (KOH or the like) is dropped onto the bases 30a of the partition walls 30 (see FIG. 1) with the protruding cross-sectional shape, forming recessed grooves whose height and breadth are 1 μm or so in the vicinities of the bases 30a. The recessed grooves serve as the insulating parts 34, and the eaves-like projections 35 of are formed above the insulating parts 34.

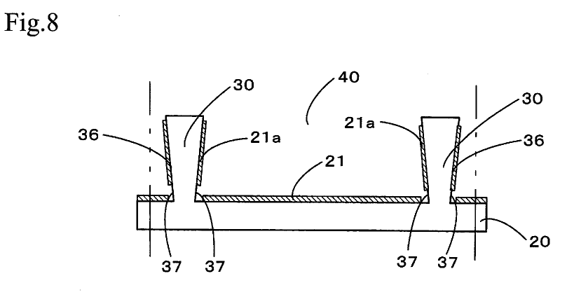

Further, the insulating parts in the invention are not limited to concavo-convex parts formed in the vicinities of the bases of the partition walls 30, such as the foregoing insulating parts 31 to 34. For example, as shown in FIG. 8, the shape of the side face 36 of the partition wall 30 may be formed into the reverse tapered shape or the reverse wedge shape so as to be tapered toward the substrate surface of the back substrate 20, so that the vicinities of the bases of the partition walls become the insulating parts 37 which the deposition material does not reach.

As a method of patterning the shapes of the side faces 36 of the partition walls 30 into a reverse tapered shape or a reverse wedge shape, for example, the quantity and etching time of the etching reagent are increased stepwise to dissolve the side faces of the partition walls 30.

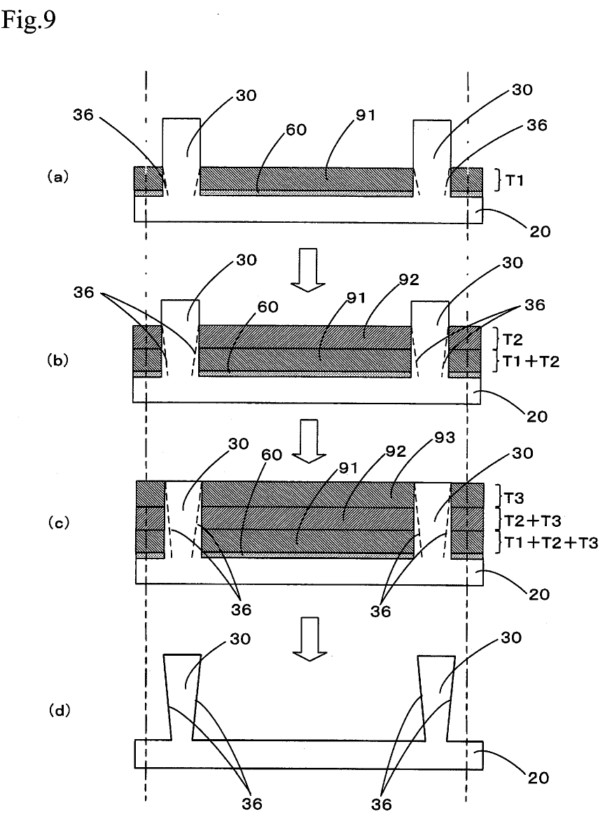

In FIG. 9(a), first, only the substrate surface of the back substrate 20 which has undergone the partition wall forming step S11 (see FIG. 3) is covered with the resist 60, and an etching reagent 91 is supplied so that liquid level may reach the vicinities of the bases of the partition walls 30, and etching is carried out for a predetermined time T1.

After passing the predetermined time T1, as shown in FIG. 9(b), an etching reagent 92 is added to the etching reagent 91 to raise the liquid level above the vicinities of the bases of the partition walls 30, and etching is carried out for a predetermined time T2. This is equivalent to etching of the vicinities of the bases of the partition walls 30 for a predetermined time T1+T2.

After passing the predetermined time T2, as shown in FIG. 9(c), an etching reagent 93 is added to the etching reagents 91 and 92 to raise the liquid level to the upper end portions of the partition walls 30, and etching is carried out for a predetermined time T3. This is equivalent to stepwise etching from the vicinities of the bases of the side faces 36 of the partition walls 30 to the upper end portions thereof for a predetermined time T1+T2+T3, the predetermined time T2+T3, and the predetermined time T3.

After passing of the predetermined time T3, the etching reagents 91 to 93 are rinsed, and the resist 60 is removed. The execution of the aforementioned stepwise etching can shape the side faces 36 of the partition walls 30 into a reverse tapered shape or a reverse wedge shape as shown in FIG. 9(d).

The method of shaping the side face 36 of the partition wall 30 into a reverse tapered shape or a reverse wedge shape is not limited to the methods shown in FIGS. 9(a) to 9(d). For example, it is also possible to shape the side face 36 of the partition wall 30 into a reverse tapered shape or a reverse wedge shape by applying to a high-concentration etching reagent, an intermediate-concentration etching reagent, and a low-concentration etching reagent to the portion from the vicinity of the base of the side face 36 of the partition wall 30 to the upper end portion thereof, thereby shaping the side face 36 into a reverse tapered shape or a reverse wedge shape.

### <Operation and Effect>

According to the manufacturing method for a charged particle migration type display panel and the charged particle migration type display panel according to the embodiment, as described above, since the insulating part 31 (32, 33, 34, 37) so shaped as to prevent a deposition material from reaching the vicinity of the base of the partition wall 30 is formed in the insulating part forming step S12, it is possible to disconnect an electric contact between the pixel electrode 21 formed on the back substrate 20, and the surplus electrode film 21a formed on the side face of the partition wall 30 in the subsequent electrode film forming step S14. Accordingly, coagulation of the charged particles 41, 42 on the side face of the partition wall 30 can be prevented at the time of applying the voltage to the pixel electrode 21. Consequently, both the response speed of the charged particles 41, 42 and the display contrast is improved, thus making it possible to achieve long-term stabilization of display quality.

### <Other Modifications>

The manufacturing method for the charged particle migration type display panel and the charged particle migration type display panel according to the invention are not limited to the foregoing embodiment. For example, although the insulating parts 31 to 34, and 37 are provided at the partition walls 30 on the back substrate 20 in the foregoing embodiment, this structure is not restrictive. For example, the invention can also be applied to a case where the common electrode 11 is vapor deposited to the rear-face side of the transparent substrate 10 which has cross-shaped partition walls 301, 301, 301, . . . integrally formed therewith as shown in FIG. 10(a). That is, it is possible to take the structure such that the insulating part 31 of a recessed groove form is formed in the vicinity of the base of the partition wall 301 which is continual to the substrate surface of the transparent substrate 10.

In addition, the invention is not limited to the active-matrix type charged particle migration type display panel 1 configured to have the pixel electrodes 21 provided at the respective cells 40 on the back substrate 20 as shown in FIG. 2, but can also be applied to, for example, a charged particle migration type display panel of a passive matrix type. In case of the passive matrix type, as shown in FIG. 10(b), partition walls 302 are laid out in a lattice form discontinuous in either the vertical direction or the horizontal direction, and lines of pixel electrodes 21 continuous in either the vertical direction or the horizontal direction are formed on the substrate surface of the back substrate 20. With such a structure, the insulating parts 31 having a shape of, for example, a recessed groove may be formed in the vicinities of the bases of the partition walls 302 which are continual to the substrate surface of the back substrate 20.

Although two colors, white and black, are used for the charged particles 41, 42 in the foregoing embodiment, which is not restrictive, the charged particle migration type display panel to which the invention is directed may be configured in such a way as to have charged particles colored with either a light color or a dark color (for example, white charged particles), and a liquid dispersion medium colored with either a dark color or a light color (for example, black liquid dispersion medium), whereby as the single-color charged particles are migrated toward the transparent substrate 10 or back substrate 20, the display is changed over.

The charged particle migration type display panel to which the invention is directed is not restricted to the structure where the color of the charged particles is white or black, but may adopt the structure which effects the display by a combination of charged particles of other colors. Further, it is possible to adopt the structure where charged particles of three colors are enclosed in a single cell 40.

The charged particle migration type display panel to which the invention is directed is not restricted to the wet structure having the liquid dispersion medium 43 enclosed in the cells 40 as in the foregoing embodiment, and may take a dry structure which does not used the liquid dispersion medium 43. Further, it is possible to adopt the structure which changes over the display by changing the distribution state of the charged particles in the cells 40 in parallel to the substrate surface.

### DESCRIPTION OF REFERENCE NUMERALS

1 charged particle migration type display panel
10 transparent substrate (substrate)
11 common electrode (electrode film)
20 back substrate (substrate)
21 pixel electrode (electrode film)
21a surplus electrode film
30, 301, 302 partition wall
30a base
31, 32, 33, 34, and 37 insulating part
35 projection
36 side face of partition wall
40 cell
41 white charged particles (light-colored charged particle)
42 black charged particles (dark-colored charged particle)
43 liquid dispersion medium
50 adhesives
60, 80 resist
70 mask
91-93 etching reagent

1. An manufacturing method for a charged particle migration type display panel which has a plurality of cells partitioned between two substrates placed opposite to each other by partition walls, and charged particles enclosed in the individual cells, the method comprising:
a partition wall forming step of forming the partition walls in one of the substrates; and an electrode film forming step of forming, by vapor deposition, an electrode film on a surface of the substrate where the partition walls are formed,
wherein an electric contact is disconnected between the electrode film formed on the substrate surface and surplus electrode film formed on a side face of the partition wall in the electrode film forming step by performing an insulating part forming step of forming an insulating part so shaped that a deposition material does not reach vicinities of at least bases of the partition walls before the electrode film forming step.

2. The manufacturing method according to claim 1, wherein a recessed groove extending along the base of the partition wall is formed as the insulating part.

3. The manufacturing method according to claim 1, wherein as the insulating part, a shape of a vicinity of the base of the partition wall has a reverse tapered shape or a reverse wedge shape to be tapered toward the substrate surface.

4. The manufacturing method according to claim 1, wherein a projection extending along the partition wall is formed above the base of the partition wall, so that the vicinity of the base becomes the insulating part so shaped that the deposition material does not reach thereto.

5. The manufacturing method according to claim 1, wherein in the insulating part forming step, the insulating part is formed by etching either at least one of the partition wall and the substrate surface.

6. The manufacturing method according to claim 1, wherein the partition wall forming step, the partition walls are formed integral on a flexible substrate as the substrate by a mold.

7. The manufacturing method according to claim 1, further comprising a step of masking an upper end portion of the partition wall with a resist before the electrode film forming step, and a step of removing the resist after the electrode film forming step, wherein an electric contact between the surplus electrode films respectively formed at the vicinities of the upper end portions on both side faces of the partition wall and an electrode film on the other substrate which is mounted on the upper end portions is disconnected.

8. A charged particle migration type display panel manufactured by the method as set forth in claim 1.

9. A charged particle migration type display device equipped with the charged particle migration type display panel according to claim 8.

10. A charged particle migration type display panel manufactured by the method as set forth in claim 2.

11. A charged particle migration type display panel manufactured by the method as set forth in claim 3.

12. A charged particle migration type display panel manufactured by the method as set forth in claim 4.

13. A charged particle migration type display panel manufactured by the method as set forth in claim 5.

14. A charged particle migration type display panel manufactured by the method as set forth in claim 6.

15. A charged particle migration type display panel manufactured by the method as set forth in claim 7.
